(19) United States
(12) Patent Application Publication
(10) Pub. No.: US 2026/0344541 A1
(43) Pub. Date: Oct. 29, 2026

(54) PACKAGE STRUCTURE AND METHOD OF FORMING THE SAME

(71) Applicant: Taiwan Semiconductor Manufacturing Company, Ltd., Hsinchu (TW)

(72) Inventors: Hsu-Hsien Chen, Hsinchu City (TW); Chen-Shien CHEN, Hsinchu County (TW); Yinlung Lu, Hsinchu (TW); Yao-Chun Chuang, Hsinchu City (TW); Jyun-Lin Wu, Hsinchu City (TW)

(73) Assignee: Taiwan Semiconductor Manufacturing Company, Ltd., Hsinchu (TW)

(21) Appl. No.: 19/192,325

(22) Filed: Apr. 28, 2025

(51) Int. Cl. H10W 90/00; H10W 40/25; H10W 70/60; H10W 70/63; H10W 70/65; H10W 74/01; H10W 74/10

(52) U.S. Cl. CPC H10W 90/701; H10W 40/25; H10W 70/611; H10W 70/635; H10W 70/65; H10W 74/01; H10W 74/111

(57) ABSTRACT

Provided is a package structure and a method of forming the same. The package structure includes an interposer having a first surface and a second surface opposite to each other; a first die and a second die arranged in parallel on the first surface of the interposer; an underfill layer disposed on the first surface of the interposer and filling into a space between the first die and the second die; and an encapsulant laterally encapsulating the first die and the second die, and covering a top surface of a portion of the underfill layer filled into the space between the first die and the second die, wherein a coefficient of thermal expansion (CTE) of the encapsulant is less than a CTE of the underfill layer.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1I illustrate cross-sectional views of intermediate stages in the formation of a package structure in accordance with some embodiments.

FIG. 2 is a schematic view illustrating the locations of the dies on the interposer in accordance with some embodiments.

FIG. 3 is a schematic view illustrating the locations of the dies on the interposer in accordance with some alternative embodiments.

FIG. 4 and FIG. 5 illustrate enlarged cross-sectional views of a region of FIG. 1F in accordance with various embodiments.

FIG. 6 illustrates a process flow for forming a package structure in accordance with some embodiments.

FIG. 7 illustrates a process flow for forming a package structure in accordance with some alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

A package structure and a method of forming the same are provided. In accordance with some embodiments of the present disclosure, the package structure may include upper dies bonded to the lower interposer, and the underfill layer surrounding the upper dies. In the formation of the package structure, a surface treatment may be performed on the dies to increase a hydrophobicity of a surface of the upper dies. In this case, the underfill layer is not completely or fully filled into the space between the upper dies due to the increased hydrophobicity, and an encapsulant formed of a stress reduction material that may help reduce stress exerted on the bonding interface of the upper dies and the lower interposer during expansion of the underfill layer at high temperatures. The yield and reliability of the package structure may thus be improved.

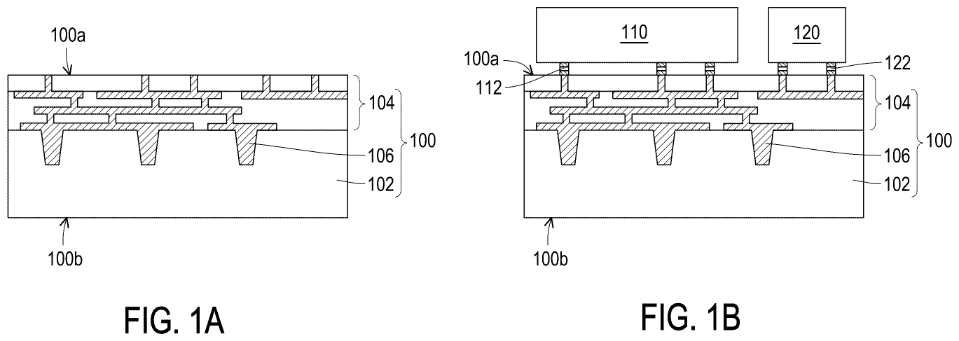

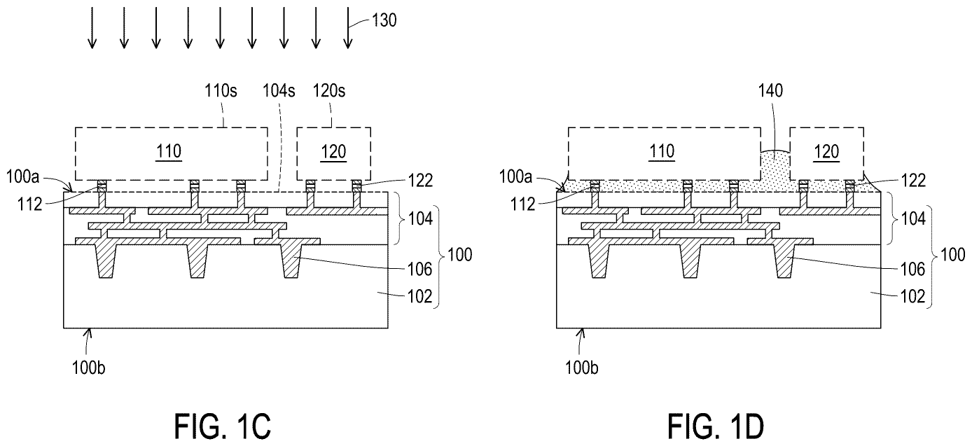

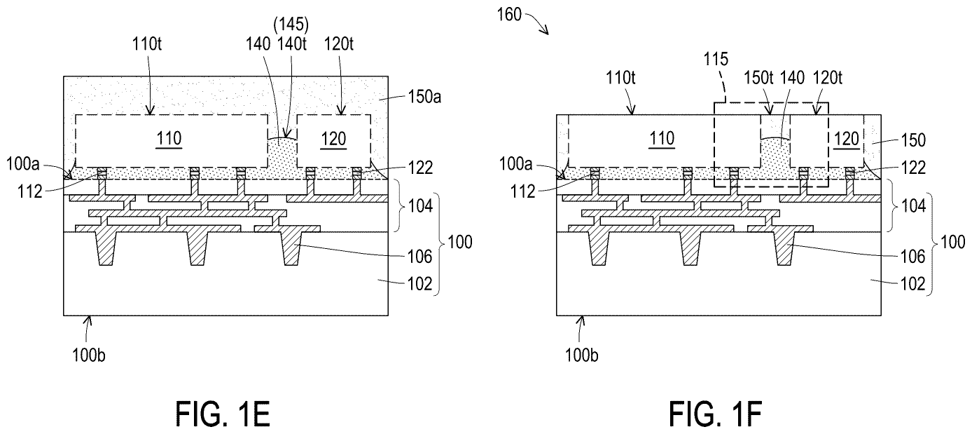

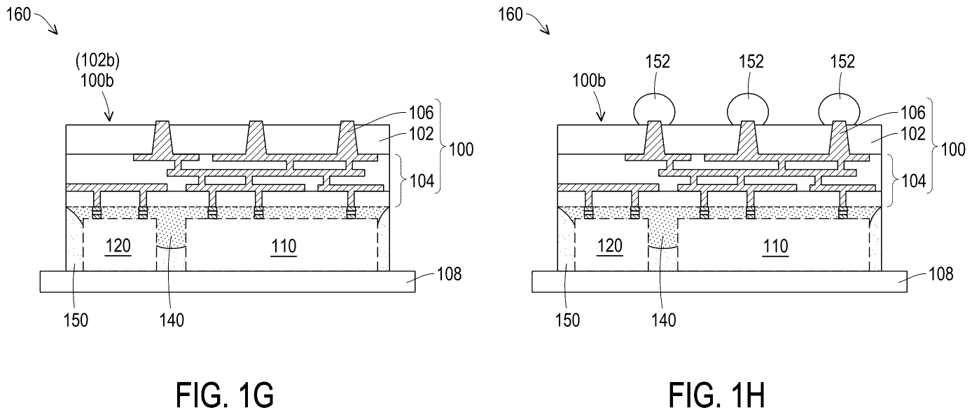

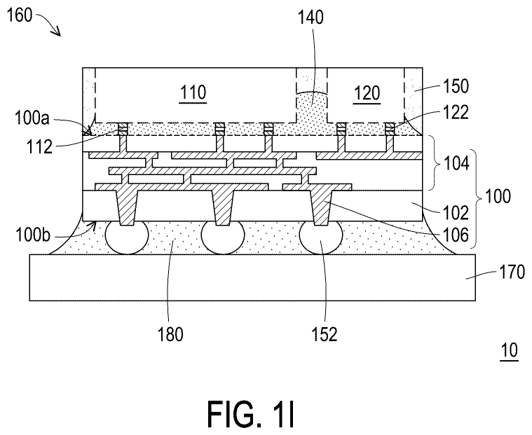

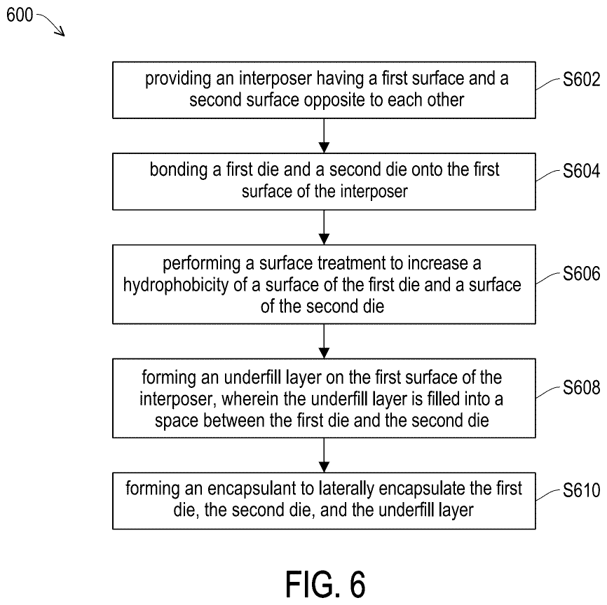

FIG. 1A to FIG. 1I illustrate cross-sectional views of intermediate stages in the formation of a package structure in accordance with some embodiments. The corresponding processes are also reflected schematically in a process flow 600 shown in FIG. 6.

Referring to FIG. 1A, an interposer 100 is provided. The respective process is shown as a step S602 in the process flow 600 as shown in FIG. 6. In some embodiments, the interposer 100 may include a semiconductor substrate 102, an interconnect structure 104, and a plurality of through-substrate vias (TSVs) 106. The interposer 100 as illustrated in FIG. 1A can be obtained or formed. The interposer 100 has a first surface 100a and a second surface 100b opposite to the first surface 100a. In some embodiments, the interposer 100 may include active or passive devices, such as transistors, memory devices, capacitors, resistors, or diodes passive devices formed in and/or on the front surface of the semiconductor substrate 102. In some alternative embodiments, the interposer 100 may only include passive devices, but does not include active devices therein. In some other embodiments, the interposer 100 may not include any active or passive devices therein. The semiconductor substrate 102 may be a bulk semiconductor substrate, a semiconductor-on-insulator (SOI) substrate, a multi-layered semiconductor substrate, or the like. The semiconductor substrate 102 may include a semiconductor material, such as silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used.

The interconnect structure 104 is disposed over the semiconductor substrate 102, and is used to electrically connect the devices (if any) of the semiconductor substrate 102 and/or the devices attached to the interconnect structure 104. The interconnect structure 104 may include one or more dielectric layer(s) and respective metallization layer(s) in the dielectric layer(s). Acceptable dielectric materials for the dielectric layers include an oxide, a nitride, a carbide, a combination thereof, or the like. For example, the dielectric material may include silicon oxide, aluminum oxide, silicon nitride, silicon oxynitride, silicon carbide, silicon oxycarbide, silicon carbonitride, silicon oxycarbonitride, a combination thereof, or the like. Other dielectric materials may also be used, such as a polymer such as polybenzoxazole (PBO), polyimide, a benzocyclobutene (BCB) based polymer, or the like. The metallization layer(s) may include conductive vias and/or conductive lines to interconnect any devices together and/or to an external device. The metallization layer(s) may be formed of a conductive material, such as a metal, which may be copper, cobalt, aluminum, gold, combinations thereof, or the like. The interconnect structure 104 may be formed by a damascene process, such as a single damascene process, a dual damascene process, a combination therefore, or the like.

The TSVs 106 may extend into the interconnect structure 104 and/or the semiconductor substrate 102. The TSVs 106 are electrically connected to metallization layer(s) of the interconnect structure 104. As an example to form the TSVs 106, recesses can be formed in the interconnect structure 104 and/or the semiconductor substrate 102 by, for example, etching, milling, laser techniques, a combination thereof, and/or the like. A thin dielectric material may be formed in the recesses, such as by using an oxidation technique. A thin barrier layer may be conformally deposited in the openings, such as by chemical vapor deposition (CVD), atomic layer deposition (ALD), physical vapor deposition (PVD), thermal oxidation, a combination thereof, and/or the like. The barrier layer may be formed of an oxide, a nitride, a carbide, combinations thereof, or the like. A conductive material may be deposited over the barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer are removed from a surface of the interconnect structure 104 or the semiconductor substrate 102 by, for example, a chemical-mechanical polish (CMP). Remaining portions of the barrier layer and conductive material form the TSVs 106. On the other hand, as shown in FIG. 1A, the TSVs 106 may buried within the second surface 100b of the interposer 100.

Referring to FIG. 1B, a first die 110 and a second die 120 are provided and mounted on the first surface 100a of the interposer 100. The respective process is shown as a step S604 in the process flow 600 as shown in FIG. 6. Only one first die and one second die are shown in the figures as exemplary examples, but the numbers of the first die(s) and second die(s) are not limited to the examples shown herein. In some embodiments, the first and second dies 110, 120 are individual semiconductor dies singulated from a wafer. In some embodiments, the first dies 110 contain the same circuitry, such as devices and metallization patterns, or the first dies 110 are the same type of dies. In some embodiments, the second dies 120 contain the same circuitry, or the second dies 120 are the same type of dies. In certain embodiments, the first die 110 and the second die 120 have different circuitry or are different types of dies. In alternative embodiments, the first die 110 and the second die 120 may have the same circuitry.

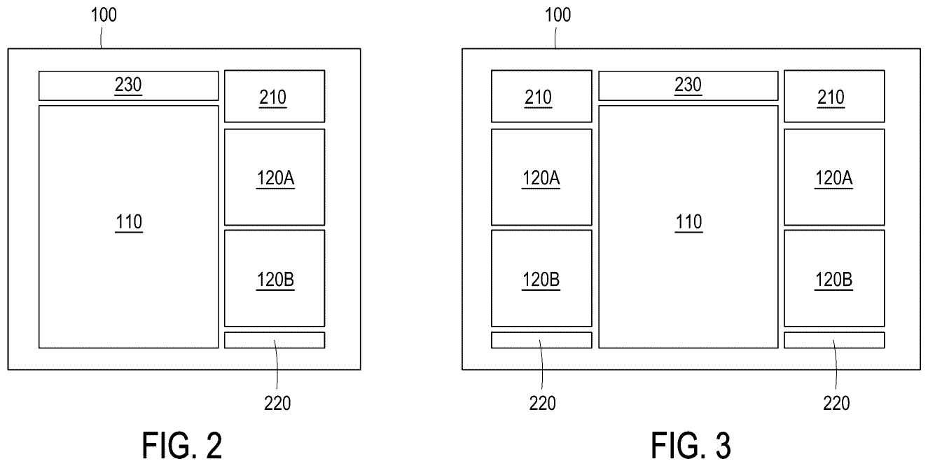

In some embodiments, the first die 110 and the second die 120 are arranged in parallel on the first surface 100a of the interposer 100. That is, the first die 110 and the second die 120 are arranged side-by-side and spaced apart from each other. The number and arrangement of the dies can be adjusted according to design requirements. For example, as shown in the plan view of FIG. 2, two second dies 120A, 120B can be arranged in parallel on one side of the first die 110. In addition, additional dies 210, 220, and 230 (e.g., dummy dies, I/O dies, filler dies, or the like) may be placed to fill the space other than the first die 110 and second dies 120A, 120B. However, the embodiments of the present disclosure are not limited thereto. In other embodiments, the second dies 120A, 120B can be arranged on opposite sides of the first die 110 in a mirror-like manner, as shown in FIG. 3.

In some embodiments, the first die 110 as a surface area larger than that of the second die 120. Also, in some embodiments, the first die 110 and the second die 120 may be of different sizes, including different surface areas and/or different thicknesses. In some embodiments, the first die 110 may be a logic die, including a central processing unit (CPU) die, a graphics processing unit (GPU) die, a system-on-a-chip (SoC) die, a microcontroller or the like. In some embodiments, the first die 110 is a power management die, such as a power management integrated circuit (PMIC) die. In some embodiments, the second die 120 may be a memory die, including a dynamic random access memory (DRAM) die, a static random access memory (SRAM) die or a high bandwidth memory (HBM) die. In some embodiments, the first die 110 includes a plurality of conductive connectors 112 formed on the active surface of the body of the first die 110. In certain embodiments, the conductive connectors 112 may further include pillar structures. In some embodiments, the second die 120 include a plurality of conductive connectors 122 formed on the active surface of the second die 120. In other embodiments, the conductive connectors 122 may further include pillar structures. In these embodiments, the material(s), the amount, and/or the size may be not limited to the descriptions provided in the embodiments.

In the present embodiment, the first die 110 is a system-on-a-chip (SoC) die which may be referred to as a silicon-based die, and the second die 120 is a high bandwidth memory (HBM) die which may be referred to as a carbon-based die. Specifically, the first die 110 may be formed in a silicon wafer, which may include different die regions that are singulated in subsequent steps to form a plurality of first dies 110. The first die 110 may include a silicon substrate, an interconnect structure over the silicon substrate, and a plurality of electrical connectors over the interconnect structure. On the other hand, the second die 120 is a stacked device that includes multiple semiconductor substrates and an encapsulant encapsulating the semiconductor substrates. For example, the second die 120 may be a memory device that includes multiple memory dies stacked alternately, and an encapsulant (e.g., an epoxy, an organic polymer, a polymer, or the like) encapsulating the memory dies.

Referring back to FIG. 1B, the first dies 110 and the second dies 120 are bonded to the first surface 100a of the interposer 100, for example, through the conductive connectors 112, 122 by way of flip-chip bonding. In certain embodiments, through performing a reflow process, the conductive connectors 112, 122 are bonded to the metallization layer of the interconnect structure 104, electrically and physically connecting the dies 110, 120 with the interposer 100. In certain embodiments, the conductive connectors 112, 122 may be micro-bumps, such as micro-bumps having copper metal pillars. The conductive connectors 112, 122 electrically connect the first dies 110 and the second dies 120, through the metallization layer of the interconnect structure 104, with the TSVs 106 of the interposer 100.

In some embodiments, the reflow process is performed as part of the bonding process to bond the first dies 110 and second dies 120 onto the redistribution structure 210 and to the interposer 100. In one embodiment, the conductive connectors 112, 122 are micro bumps, and the reflow temperature ranges from 210 Celsius degrees to 250 Celsius degrees, or at about 240 Celsius degrees. In some alternative embodiments, the bonding between the dies 110, 120 and the interposer 100 may be solder bonding.

Referring to FIG. 1C, a surface treatment 130 is performed. The respective process is shown as a step S606 in the process flow 600 as shown in FIG. 6. In some embodiments, the surface treatment 130 may be performed on the first die 110 and the second die 120 to increase a hydrophobicity of a surface 110s of the first die 110 and a surface 120s of the second die 120. Specifically, the surface treatment 130 may include reacting the surface 110s of the first die 110 and the surface 120s of the second die 120 with an alkyl halide (e.g., CF₄, CCl₄, CBr₄) or the like, so that the surface 110s of the first die 110 and the surface 120s of the second die 120 are changed to hydrophobic surfaces. In some embodiments, the surface treatment 130 includes converting the polar or hydrophilic end groups, like hydroxyl (—OH) end groups, on the surface 110s of the first die 110 and the surface 120s of the second die 120 to non-polar or hydrophobic end groups, like methyl groups (—CH₃). For example, the surface treatment 130 may include a plasma process using a reaction gas having O₂ and CH₃, wherein O₂ may be used to convert the surface 110s of the first die 110 and the surface 120s of the second die 120 into the polar or hydrophilic end groups, like hydroxyl (—OH) end groups. In addition, CH₃ may be used to replace or convert the polar or hydrophilic end groups, into the non-polar or hydrophobic end groups, like methyl groups (—CH₃).

In some embodiments, the surface treatment 130 may include a plasma process, and a reaction gas of the plasma process may include: O₂ and CF₄, CCl₄, CBr₄, CH₃, or the like. Take CF₄ as an example, during the plasma fluorination process, fluorine-containing free radicals would adsorb on the surface of the silicon source/carbon source to form Si—F/C—F bonds, thereby forming fluorinated silicon/fluorinated carbon materials. Since fluorine is a material with low surface energy, the formation of silicon fluoride/carbon fluoride materials can effectively reduce the polarity and surface energy of the material, thereby improving the hydrophobicity of the surface 110s of the first die 110 and the surface 120s of the second die 120. In the present embodiment, the surface treatment 130 may be referred to as a hydrophobic treatment. It should be noted that the fluorine content at the surface 110s of the first die 110 and/or the surface 120s of the second die 120 can be detected by X-ray Photoelectron Spectroscopy (XPS) or Energy-Dispersive x-ray Spectroscopy (EDS). In some embodiments, compared with the dies without performing the hydrophobic treatment, the fluorine content at the surface 110s of the first die 110 and/or the surface 120s of the second die 120 can be increased by about 2 to 10 times.

In some alternative embodiments, the surface treatment 130 may include a plasma process using a reaction gas having O₂ and CF₄, wherein O₂ may be used to change the surface 110s of the first die 110 and the surface 120s of the second die 120 into the polar or hydrophilic end groups, like hydroxyl (—OH) end groups. In addition, CF₄ may be used to replace or convert the polar or hydrophilic end groups, into the non-polar or hydrophobic end groups, like trifluoromethyl groups (—CF₃). In such embodiment, the fluorine content at the surfaces 110s/120s of the hydrophobic treatment with O₂ is less than the fluorine content at the surfaces 110s/120s of the hydrophobic treatment without O₂.

In some embodiments, the surface treatment 130 is performed after bonding the first die 110 and the second die 120 onto the first surface 100a of the interposer 100, as shown in the process flow 600 of FIG. 6. In this case, not only the surfaces 110s, 120s are modified, but also a surface 104s of the interconnect structure 104 is modified by the surface treatment 130 to increase the hydrophobicity of the surface 104s.

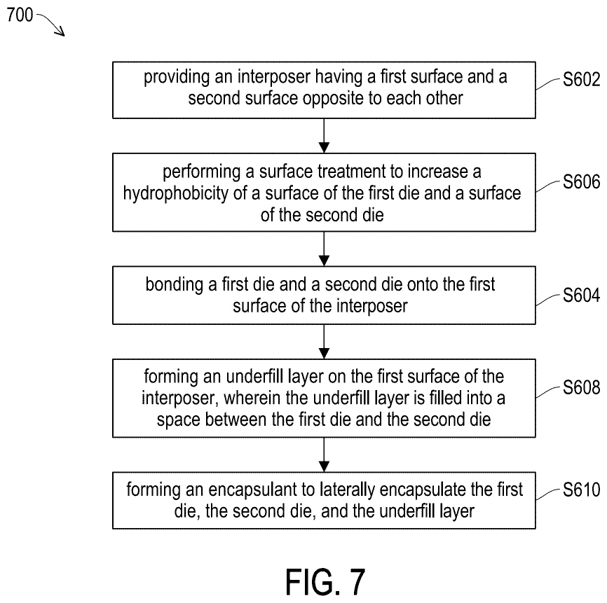

In some alternative embodiments, the surface treatment 130 is performed before bonding the first die 110 and the second die 120 onto the first surface 100a of the interposer 100, as shown in a process flow 700 of FIG. 7. In this case, only the surfaces 110s, 120s are modified to be more hydrophobic. That is, after the surfaces 110s, 120s are modified by the surface treatment 130, the first die 110 and the second die 120 are bonded onto the first surface 100a of the interposer 100. In this case, the surface 104s of the interconnect structure 104 is not modified and maintains its original properties. In some alternative embodiments, only the surface 110s of the first die 100 or only the surface 120s of the second die 120 may be modified to be more hydrophobic according to the requirements. In some other embodiments, only the local region of first die 100 and the second die 120 are modified to be more hydrophobic by the surface treatment 130, such as the facing sidewalls of the first die 100 and the second die 120.

Referring to FIG. 1D, an underfill layer 140 is formed on the first surface 100a of the interposer 100. The respective process is shown as a step S608 in the process flow 600 as shown in FIG. 6. Specifically, the underfill layer 140 may be formed to laterally surround the conductive connectors 112, 122. In some embodiments, the underfill layer 140 may extend between the first die 110 and the first surface 100a of the interposer 100 and between the second die 120 and the first surface 100a of the interposer 100, and be in direct contact the conductive connectors 112, 122. In addition, the underfill layer 140 is filled into a space (or gap) between the first die 110 and the second die 120, and further covers a portion of the sidewall of the first die 110 and a portion of the sidewall of the second die 120. In some embodiments, the underfill layer 140 may be any acceptable material, such as a polymer, epoxy, molding underfill, or the like. The underfill layer 140 may be formed by a capillary flow process after the first die 110 and the second die 120 are attached or may be formed by a suitable deposition method before the first die 110 and the second die 120 is attached.

Next, the underfill layer 140 is cured using a curing process, in some embodiments. The curing process may include heating the underfill layer 140 to a predetermined temperature for a predetermined period of time, using an anneal process or other heating process. The curing process may also include an ultra-violet (UV) light exposure process, an infrared (IR) energy exposure process, combinations thereof, or a combination thereof with a heating process. Alternatively, the underfill layer 140 may be cured using other methods. In some embodiments, a curing process is not included.

After curing the underfill layer 140, as shown in FIG. 1E, an encapsulating material 150a is then formed to laterally encapsulate the first die 110, the second die 120, and the underfill layer 140. The respective process is shown as a step S610 in the process flow 600 as shown in FIG. 6. Specifically, the encapsulating material 150a may overlay a top surface 140t of a portion of the underfill layer 140 filled into the space between the first die 110 and the second die 120, and further cover a top surface 110t of the first die 110 and a top surface 120t of the second die 120. In some embodiments, the encapsulating material 150a may include an epoxy, an organic polymer, a polymer with or without a silica-based filler or glass filler added, or other materials, as examples. In some embodiments, the encapsulating material 150a includes a liquid molding compound (LMC) that is a gel type liquid when applied. The encapsulating material 150a may also include a liquid or solid when applied. Alternatively, the encapsulating material 150a may include other insulating and/or encapsulating materials. The encapsulating material 150a is applied using a wafer level molding process in some embodiments. The encapsulating material 150a may be molded using, for example, compressive molding, transfer molding, molded underfill (MUF), or other methods. In some embodiments, the encapsulating material 150a and the underfill layer 140 have different materials. In this case, an interface 145 may be formed between the encapsulating material 150a and the underfill layer 140. As shown in FIG. 1E, the cross-section of the interface 145 is in a bowing shape with an upwardly protruding surface (i.e. crying profile). The detailed description can be given in the following paragraphs.

Next, the encapsulating material 150a is cured using a curing process, in some embodiments. The curing process may include heating the encapsulating material 150a to a predetermined temperature for a predetermined period of time, using an anneal process or other heating process. The curing process may also include an ultra-violet (UV) light exposure process, an infrared (IR) energy exposure process, combinations thereof, or a combination thereof with a heating process. Alternatively, the encapsulating material 150a may be cured using other methods. In some embodiments, a curing process is not included.

Referring to FIG. 1F, a planarization process is performed on the encapsulating material 150a to expose the top surface 110t of the first die 110 and the top surface 120t of the second die 120. In some embodiments, the planarization process includes a chemical mechanical polishing (CMP) process, and may be performed to remove excess portions of the encapsulating material 150a, such that the formed encapsulant 150, the first die 110, and the second die 120 have a coplanar upper surface. That is, the top surface 110t of the first die 110, the top surface 120t of the second die 120, and a top surface 150t of the encapsulant 150 are substantially coplanar (within process variations). In some alternative embodiments, a portion of the encapsulant 150 may cover the top surface 110t of the first die 110 and the top surface 120t of the second die 120 after the planarization process.

In some embodiments, a coefficient of thermal expansion (CTE) of the first die 110 may be largely determined by a CTE of the semiconductor substrate, which are formed of a semiconductor material such as silicon. The underfill material may surrounds and protects the first die 110 and the second die 120, and is further filled in the space between the first die 110 and the second die 120. However, the underfill material has a large CTE as compared to the semiconductor material of the first die 110. As a result, the underfill material may expand more than the first die 110 at high temperatures. Expansion of the underfill material at high temperatures can exert stress on the bonding interfaces of the first die 110 and the interposer 100, especially when the underfill material is fully filled into the narrow space between the larger size first die 110 and the second die 120, the said stress would be further increased. In this case, the increased stress will result in the crack issue of the underfill material, and even increase the risk of delamination of the dielectric layers of the first die 110.

In order to solve the above issues, the present embodiment reduces the content of the underfill material filled into the narrow space between the first die 110 and the second die 120 to reduce the stress exerted on the bonding interface due to the CTE mismatch. In detail, the surface treatment 130 may be performed on the first die 110 and the second die 120 to increase the hydrophobicity of the surface 110s of the first die 110 and the surface 120s of the second die 120. In this case, the underfill layer 140 is not easily attached onto the surface 110s of the first die 110 and the surface 120s of the second die 120 in the capillary flow process, and thus is not completely or fully filled into the space between the first die 110 and the second die 120. The encapsulant 150 with a lower CTE than the underfill layer 140 is then filled into the space between the first die 110 and the second die 120 to reduce the overall CTE of the space between the first die 110 and the second die 120. The encapsulant 150 may reduce stress exerted on the bonding interface as a result of CTE mismatch. Specifically, the CTE of the encapsulant 150 may be between the CTE of the underfill layer 140 and the CTE of the first die 110. In other words, the CTE of the encapsulant 150 is greater than the CTE of the first die 110, while the CTE of the encapsulant 150 is less than the CTE of the underfill layer 140. In some embodiments, the first die 110 has a CTE in the range of 2 ppm/°C to 3 ppm/°C, the encapsulant 150 has a CTE in the range of 5 ppm/°C to 15 ppm/°C, and the underfill layer 140 has a CTE in the range of 20 ppm/°C to 30 ppm/°C. Thus, the encapsulant 150 may reduce stress caused by a CTE mismatch between the underfill layer 140 and the first die 110, which may reduce the crack issue of the underfill material and the risk of the dielectric layers of the first die 110 delaminating (specifically, at the edges of the first die 110). The yield and reliability of the subsequently formed package structure 10 (FIG. 1I) may thus be improved.

In some embodiments, the encapsulant 150 is formed of a stress reduction material that helps reduce stress exerted on the bonding interfaces of the first die 110 and the interposer 100. The stress reduction material may include a polymer material and optionally includes a filler. The polymer material may be a polyester, a polyamide, a polycarbonate, a polyurethane, or the like. For example, the polymer material may be a thermoplastic polymer such as polyethylene terephthalate. The filler is formed of a material that provides mechanical strength for the encapsulant 150, such as particles of silica (SiO₂). The stress reduction material of the encapsulant 150 optionally includes a filler. When a filler is used, the CTE of the stress reduction material may be tuned to a desired amount by controlling the filler type (e.g., material), filler load (e.g., quantity of filler), and/or average filler particle size. Thus, the stress reduction material may be formed with a desired CTE between the CTE of the underfill layer 140 and the CTE of the first die 110. In some alternative embodiments, the underfill layer 140 may include a first encapsulation material, the encapsulant 150 may include a second encapsulation material, and the second encapsulation material and the first encapsulation material have different materials with different CTE.

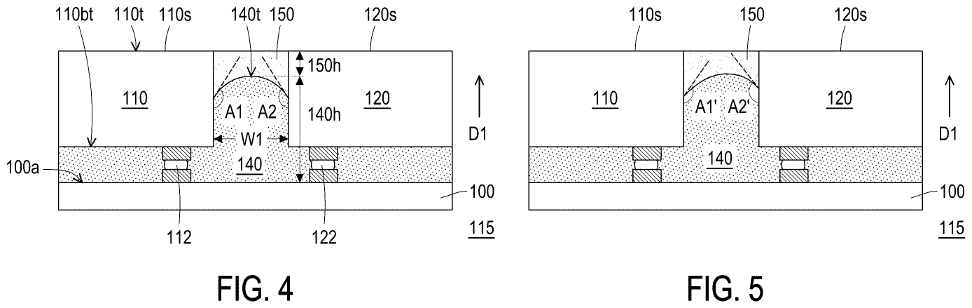

FIG. 4 and FIG. 5 illustrate enlarged cross-sectional views of a region 115 of FIG. 1F in accordance with various embodiments.

Referring to FIG. 1F and FIG. 4, the underfill layer 140 may have the top surface 140t protruding along a direction D1 from the second surface 100b of the interposer 100 toward the first surface 100a of the interposer 100. That is, the top surface 140t of the underfill layer 140 is in a bowing shape with an upwardly protruding surface (i.e. crying profile). In some embodiments, the top surface 140t of the underfill layer 140 is vertically disposed between a top surface 110t of the first die 110 and a bottom surface 110bt of the first die 100. In other words, the underfill layer 140 is not completely or fully filled into the space between the first die 110 and the second die 120 due to the increased hydrophobicity, and the encapsulant 150 formed of a lower CTE material than the underfill layer 140 may help reduce stress exerted on the bonding interface of the upper dies 110, 120 and the lower interposer 100, thereby improving the yield and reliability of the package structure. In this case, the encapsulant 150 may be referred to as a stress reduction material or a CTE reduction material. In some embodiments, a first contact angle A1 between the top surface 140t of the underfill layer 140 and a sidewall of the first die 110 is an obtuse angle due to the increased hydrophobicity of the surface 110s of the first die 110. Similarly, a second contact angle A2 between the top surface 140t of the underfill layer 140 and a sidewall of the second die 120 is an obtuse angle due to the increased hydrophobicity of the surface 120s of the second die 120. In some embodiments, the first contact angle A1 and/or the first contact angle A2 is the range of 90 degree to 170 degree. In some embodiments, the first contact angle A1 is the same as the first contact angle A2, as shown in FIG. 4. For example, the first die 110 is a system-on-a-chip (SoC) die and the second die 120 is a dummy die, and both of the first die 110 and the second die 120 are referred to as silicon-based dies. In this case, the underfill layer 140 may have a symmetric top surface (within process variations). However, the embodiments of the present disclosure are not limited thereto. In other embodiments, the first contact angle A1′ is different from the first contact angle A2′, as shown in FIG. 5. Specifically, the first die 110 is a system-on-a-chip (SoC) die which may be referred to as a silicon-based die, and the second die 120 is a high bandwidth memory (HBM) die which may be referred to as a carbon-based die. The carbon-based surface 120s of the second die 120 is more hydrophobic than the silicon-based surface 110s of the first die 110 after performing the surface treatment 130. As a result, the first contact angle A2′ may be greater than the first contact angle A1′. In this case, the underfill layer 140 may have an asymmetric top surface.

In some embodiments, the underfill layer 140 filled into the space between the first die 110 and the second die 120 has a height 140h in the range of 30 μm to 650 μm, wherein the height 140h is measured from the first surface 100a of the interposer 100 to the top surface 140t of the underfill layer 140. Selecting the height 140h of greater than or substantially equal to 30 μm can at least surround and protect the conductive connectors 112 and 122. Selecting the height 140h of less than or substantially equal to 650 μm can reduce the stress exerted on the bonding interface due to the CTE mismatch. In some embodiments, the encapsulant 150 filled into the space between the first die 110 and the second die 120 and covering the top surface 140t of the underfill layer 140 has a height 150h in the range of 680 μm to 60 μm, the sum of the height 140h and the height 150h is about 710 μm, and a ratio of the height 150h to the height 140h is about 0.04 to about 10.83. The greater height 150h is, the lower the overall CTE in the space between the first die 110 and the second die 120 is, thereby reducing the stress exerted on the bonding interface due to the CTE mismatch. In some embodiments, the space between the first die 110 and the second die 120 has a width W1 in the range of 10 μm to 500 μm. The smaller width W1 is, the more focus the stress is, and the more it is necessary to reduce the content of the underfill layer 140 to reduce the stress exerted on the bonding interface. As such, as the demand for shrinking electronic devices has grown, the present embodiment reduces the stress due to the CTE mismatch by decreasing the content of the underfill layer 140 filled into the space between the first die 110 and the second die 120 and can be applied to a compact packaging structure.

Referring back to FIG. 1F to FIG. 1G, an overlying structure 160 of FIG. 1F is flipped or turned upside down, and placed on a carrier 108. Specifically, the first die 110, the second die 120, and the encapsulant 150 face downward and are attached onto the carrier 108, while the second surface 100b of the interposer 100 faces upward. In some embodiments, the overlying structure 160 may be attached onto the carrier 108, e.g., through an adhesive layer (not shown). The adhesive layer may be photosensitive and may be easily detached from the carrier 108 by shining, e.g., an ultra-violet (UV) light on the carrier 108 in a subsequent carrier de-bonding process. For example, the adhesive layer may be a light-to-heat-conversion (LTHC) coating.

After attaching to the carrier 108, a thinning process is performed on the second surface 100b of the interposer 100. Specifically, the thinning process may be performed to remove a portion of the semiconductor substrate 102 until exposing the TSVs 106 in the interposer 100. In some embodiments, the thinning process s includes a grinding process, a chemical mechanical polishing (CMP) process, the like, or any suitable process. After performing the thinning process, the TSVs 106 may protrude from the backside 102b of the semiconductor substrate 102 (or the second surface 100b), as shown in FIG. 1G. However, the embodiments of the present disclosure are not limited thereto. In other embodiments, the top surfaces of the TSVs 106 and the backside 102b of the semiconductor substrate 102 may be substantially coplanar (within process variations).

Referring to FIG. 1H, a plurality of external connectors 152 are respectively formed on the TSVs 106 for external connection to the interconnect structure 104. The external connectors 152 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The external connectors 152 may include a conductive material such as solder, copper, aluminum, gold, nickel, silver, palladium, tin, the like, or a combination thereof. In some embodiments, the external connectors 152 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the external connectors 152 include metal pillars (such as a copper pillar) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

Referring to FIG. 1H and FIG. 1I, a carrier de-bonding is performed to detach (or “de-bond”) the carrier 108 from an overlying structure 160. In some embodiments, the de-bonding includes projecting a light such as a laser light or an UV light on the adhesive layer between the carrier 108 and the encapsulant 150, so that the adhesive layer decomposes under the heat of the light and the carrier 108 can be removed.

Referring to FIG. 1I, the structure 160 may be bonded onto a circuit substrate 170, thereby accomplishing a package structure 10. In detail, the structure 160 may be bonded onto the circuit substrate 170 by the external connectors 152. In some embodiments, the circuit substrate 170 includes one or more active devices and/or one or more passive devices (not shown) therein. A wide variety of devices such as transistors, capacitors, resistors, combinations of these, and the like may be used to provide structural and functional designs for the device stack. The devices may be formed using any suitable methods.

In some embodiments, the circuit substrate 170 includes a substrate core (not shown). The substrate core may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the substrate core may be an SOI substrate. Generally, an SOI substrate includes a layer of a semiconductor material such as epitaxial silicon, germanium, silicon germanium, SOI, SGOI, or combinations thereof. The substrate core is, in one alternative embodiment, based on an insulating core such as a fiberglass reinforced resin core. One example core material is fiberglass resin such as FR4. Alternatives for the core material include bismaleimide-triazine BT resin, or alternatively, other PCB materials or films. Build up films such as ABF or other laminates may be used for substrate core.

The circuit substrate 170 may also include metallization layers and vias (not shown) therein. The metallization layers may be formed over the active and passive devices in and/or on the substrate core, and are designed to connect the various devices to form functional circuitry. The metallization layers may be formed of alternating layers of dielectric material (e.g., low-k dielectric material) and conductive material (e.g., copper) with vias interconnecting the layers of conductive material and may be formed through any suitable process (such as deposition, damascene, dual damascene, or the like). In some alternative embodiments, the substrate core is substantially free of active and passive devices.

After bonding the structure 160 onto the circuit substrate 170, an additional underfill layer 180 is formed on the second surface 100b of the interposer 100 to laterally surround the external connectors 152. In some embodiments, the additional underfill layer 180 may be any acceptable material, such as a polymer, epoxy, molding underfill, or the like. The additional underfill layer 180 may be formed by a capillary flow process after the structure 160 and the circuit substrate 170 are attached. In addition, the package structure 10 may optionally include a heat sink overlying the first die 110, the second die 120, and the encapsulant 150 for heat dissipation.

According to some embodiments, a package structure includes an interposer having a first surface and a second surface opposite to each other; a first die and a second die arranged in parallel on the first surface of the interposer; an underfill layer disposed on the first surface of the interposer and filling into a space between the first die and the second die; and an encapsulant laterally encapsulating the first die and the second die, and covering a top surface of a portion of the underfill layer filled into the space between the first die and the second die, wherein a coefficient of thermal expansion (CTE) of the encapsulant is less than a CTE of the underfill layer.

In some embodiments, the top surface of the underfill layer protrudes along a direction from the second surface of the interposer toward the first surface of the interposer. In some embodiments, a first contact angle between the underfill layer and the first die is an obtuse angle. In some embodiments, a second contact angle between the underfill layer and the second die is greater than the first contact angle. In some embodiments, the first die has a size greater than a size of the second die. In some embodiments, the package structure further includes: a plurality of conductive connectors, wherein the first die and the second die are bonded to the first surface of the interposer through the plurality of conductive connectors. In some embodiments, the underfill layer extends between the first die and the first surface of the interposer and between the second die and the first surface of the interposer, and laterally encapsulates the plurality of conductive connectors. In some embodiments, the package structure further includes: a plurality of external connectors disposed on the second surface of the interposer; and a circuit substrate bonded to the second surface of the interposer through the plurality of external connectors.

According to some embodiments, a method of forming a package structure includes: providing an interposer having a first surface and a second surface opposite to each other; bonding a first die and a second die onto the first surface of the interposer; performing a surface treatment to increase a hydrophobicity of a surface of the first die and a surface of the second die; forming an underfill layer on the first surface of the interposer, wherein the underfill layer is filled into a space between the first die and the second die; and forming an encapsulant to laterally encapsulate the first die and the second die, and cover a top surface of a portion of the underfill layer filled into the space between the first die and the second die.

In some embodiments, the surface treatment comprises reacting the surface of the first die and the surface of the second die with an alkyl halide through a plasma process. In some embodiments, the surface treatment is performed before bonding the first die and the second die onto the first surface of the interposer. In some embodiments, the surface treatment is performed after bonding the first die and the second die onto the first surface of the interposer. In some embodiments, the top surface of the underfill layer protrudes along a direction from the second surface of the interposer toward the first surface of the interposer. In some embodiments, after forming the encapsulant, the method further comprises: performing a thinning process on the second surface of the interposer to expose a plurality of through-substrate vias (TSVs) in the interposer. In some embodiments, the method further includes: forming a plurality of external connectors on the plurality of TSVs; and bonding a circuit substrate to the second surface of the interposer through the plurality of external connectors. In some embodiments, a first contact angle between the underfill layer and the first die is an obtuse angle. In some embodiments, a second contact angle between the underfill layer and the second die is greater than the first contact angle.

According to some embodiments, a package structure includes a first die and a second die arranged in parallel on an interposer; a first encapsulation material filling into a space between the first die and the second die, wherein a first contact angle between a top surface of the first encapsulation material and a sidewall of the first die is an obtuse angle; and a second encapsulation material overlying the top surface of the first encapsulation material, wherein the second encapsulation material and the first encapsulation material have different materials.

In some embodiments, a second contact angle between the top surface of the first encapsulation material and a sidewall of the second die is an obtuse angle. In some embodiments, the top surface of the first encapsulation material is vertically disposed between a top surface of the first die and a bottom surface of the first die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
an interposer having a first surface and a second surface opposite to each other;
a first die and a second die arranged on the first surface of the interposer;
an underfill layer disposed on the first surface of the interposer and filling into a space between the first die and the second die; and
an encapsulant laterally encapsulating the first die and the second die, and covering a top surface of a portion of the underfill layer filled into the space between the first die and the second die, wherein a coefficient of thermal expansion (CTE) of the encapsulant is less than a CTE of the underfill layer.

2. The package structure of claim 1, wherein the top surface of the underfill layer protrudes along a direction from the second surface of the interposer toward the first surface of the interposer.

3. The package structure of claim 1, wherein a first contact angle between the underfill layer and the first die is an obtuse angle.

4. The package structure of claim 3, wherein a second contact angle between the underfill layer and the second die is greater than the first contact angle.

5. The package structure of claim 1, wherein the first die has a size greater than a size of the second die.

6. The package structure of claim 1, further comprising: a plurality of conductive connectors, wherein the first die and the second die are bonded to the first surface of the interposer through the plurality of conductive connectors.

7. The package structure of claim 6, wherein the underfill layer extends between the first die and the first surface of the interposer and between the second die and the first surface of the interposer, and laterally encapsulates the plurality of conductive connectors.

8. The package structure of claim 1, further comprising:
a plurality of external connectors disposed on the second surface of the interposer; and
a circuit substrate bonded to the second surface of the interposer through the plurality of external connectors.

9. A method of forming a package structure, comprising:
providing an interposer having a first surface and a second surface opposite to each other;
bonding a first die and a second die onto the first surface of the interposer;
performing a surface treatment to increase a hydrophobicity of a surface of the first die and a surface of the second die;
forming an underfill layer on the first surface of the interposer, wherein the underfill layer is filled into a space between the first die and the second die; and
forming an encapsulant to laterally encapsulate the first die and the second die, and cover a top surface of a portion of the underfill layer filled into the space between the first die and the second die.

10. The method of claim 9, wherein the surface treatment comprises reacting the surface of the first die and the surface of the second die with an alkyl halide through a plasma process.

11. The method of claim 9, wherein the surface treatment is performed before bonding the first die and the second die onto the first surface of the interposer.

12. The method of claim 9, wherein the surface treatment is performed after bonding the first die and the second die onto the first surface of the interposer.

13. The method of claim 9, wherein the top surface of the underfill layer protrudes along a direction from the second surface of the interposer toward the first surface of the interposer.

14. The method of claim 9, wherein after forming the encapsulant, the method further comprises: performing a thinning process on the second surface of the interposer to expose a plurality of through-substrate vias (TSVs) in the interposer.

15. The method of claim 14, further comprising:
forming a plurality of external connectors on the plurality of TSVs; and
bonding a circuit substrate to the second surface of the interposer through the plurality of external connectors.

16. The method of claim 9, wherein a first contact angle between the underfill layer and the first die is an obtuse angle.

17. The method of claim 16, wherein a second contact angle between the underfill layer and the second die is greater than the first contact angle.

18. A package structure, comprising:
a first die and a second die arranged on an interposer;
a first encapsulation material filling into a space between the first die and the second die, wherein a first contact angle between a top surface of the first encapsulation material and a sidewall of the first die is an obtuse angle; and
a second encapsulation material overlying the top surface of the first encapsulation material, wherein the second encapsulation material and the first encapsulation material have different materials.

19. The package structure of claim 18, wherein a second contact angle between the top surface of the first encapsulation material and a sidewall of the second die is an obtuse angle.

20. The package structure of claim 18, wherein the top surface of the first encapsulation material is vertically disposed between a top surface of the first die and a bottom surface of the first die.
